(19) United States
(12) Patent Application Publication
(10) Pub. No.: US 2013/0248467 A1
(43) Pub. Date: Sep. 26, 2013

(54) FRAME SYSTEM FOR FIXING PANELS TO THE GROUND AT AN ANGLE

(71) Applicant: Johannes Lieuwe Wever, Apeldoorn (NL)

(72) Inventor: Johannes Lieuwe Wever, Apeldoorn (NL)

(21) Appl. No.: 13/990,049

(22) PCT Filed: Dec. 6, 2011
(86) PCT No.: PCT/NL11/50837

§ 371 Date: May 29, 2013

(30) Foreign Application Priority Data
Dec. 7, 2010 (NL) 2005826

(51) Int. Cl. F24J 2/52; H01L 31/045

(52) U.S. Cl. CPC F24J 2/52; H01L 31/045
USPC 211/41.1; 29/592.1

(57) ABSTRACT

A frame system for fixing a panel, in particular a solar panel, to the ground and oriented at an angle of 5-70 degrees to the horizontal plane. The frame system includes a front end, a rear end, a panel frame for holding the panel and provided with at least one rear support element. The rear support element at one end thereof is hingingly attached at or near the rear end to the panel frame to allow the rear support element to be folded against or in plane with the panel frame and at its other end that includes attachment provisions configured to attach the rear support element to the ground. The panel frame further includes attachment provisions configured to attach the front end of the panel to the ground.

### CROSS-REFERENCE TO RELATED APPLICATIONS

The present application is a National Stage Application of PCT International Application No. PCT/NL2011/050837 (filed on Dec. 6, 2011), under 35 U.S.C. §371, which claims priority to Dutch Patent Application No. 2005826 (filed on Dec. 7, 2010), which are each hereby incorporated by reference in their respective entireties.

### TECHNICAL FIELD

The present invention relates to a frame system for fixing panels to the ground at a desired angle of in general between 5° and 70°, and to a method for providing a photovoltaic power system on a piece of land.

### BACKGROUND

Such a frame is in general known. U.S. Pat. No. 5,125,608 discloses a photovoltaic panel support assembly that has a set of horizontal supports attached to photovoltaic panels or solar panels, and front posts and rear posts attached to these supports and having provisions for attaching these posts to the ground. The publication seeks to provide a support assembly that is easy to construct and install and that is low cost. The support assembly requires transportation of many components and panels that need to be assembled on site.

U.S. Patent Publication No. 2009/0256046 discloses an erection system for a photovoltaic open-space installation support stand. This publication seeks to provide such an erection system that can be erected more easily and quickly than previously. The system has a column which is pile-driven by its bottom section in the ground, an inclined beam attached to the column and a brace pivotingly connected to the column and slidingly to the inclined beam. The inclined beam carries module support profiles which can be attached to photovoltaic modules. This system already improves the support assembly of U.S. Pat. No. 5,125,608, but still requires many parts to be assembled on site. Furthermore, the single column puts high demands on its construction.

WO2010/057781 shows another mounting arrangement for solar panels. This mounting arrangement should be easy to install and to adaptable to the topographic situation. It has several beams that are fixed together via screw mounting. The upper surface of one of the beams is curved so as to be able to adapt to uneven pieces of land. The construction as such is further rather straightforward and must be erected on site.

Further known systems comprise the “Sunfix” system of Solarworld. Longitudinal beams supporting a plurality of panels are supported by leg structures. Each leg structure has three parts that are hingingly coupled to one another in a “Z”. One end is attached to a panel support frame, the first connection is fixed to the ground, the next connection is fixed to the panel support end the other end is again fixed to the ground. The length of each leg part is adjustable. This system again required a frame to be erected first.

U.S. Pat. No. 4,421,943 discloses an apparatus for collecting solar energy and converting it to electrical energy utilizing solar panels pivotally mounted to a base such that the panels may be pivoted to a storage position inside said base. Additional solar panels may be pivotally mounted on retractable frame trays which stow inside the base when the panels are pivoted to a horizontal position.

U.S. Pat. No. 6,046,399 discloses a roof assembly that includes a plurality of insulation blocks disposed as a layer over a water-tight roofing membrane, a plurality of metal plates bonded to selected insulation blocks, each metal plate having at least one mounting bracket thereon for mounting at least one solar panels on the roof. Spacer struts are used to locate the solar panel at an optimum angle of an inclination relative to the roof. The use of metal plates bonded to the insulation blocks provides sufficient strength to withstand wind loads and avoids the cost and weight of conventional ballast systems.

In every country there is are lots of areas of land that are temporarily not in use. Such an area of land can for example be in industrial areas, agricultural land, natural land, privately owned land or land that is dedicated for a certain function, but not being used yet, like building plots, harbour areas, etc. The inventor realised that those unused parts of land can be used to temporarily generate solar-based energy. There are many land-based systems, as illustrated above. These frames, however, remain relatively complex, expensive and take time to set up and break down. They can therefore not be used in temporary situations.

### SUMMARY

The invention aims to improve the current frames of the type referred to above.

Another objective of the invention is to provide a frame that is cheap to produce.

Yet another objective of the invention is to provide a frame that allows a set of panels, in particular photovoltaic panels, to be set up, removed and stored easily and quickly.

Another or further objective of the invention is to provide a frame that allows that the angle of the installed solar panel can be changed quickly and easily, for optimal power production in all seasons.

Yet another objective of the invention is to provide a solar panel system, that consists of one or more solar panel modules with integrated mounting systems and weights and other materials for stability, wind resistance and safety. The solar panels can be mechanically connected to each other for wind resistance and safety. The frame allows the solar panels to be electrically connected to a central collection point. The electricity is preferably converted and delivered to the electricity grid.

According to a first aspect of the invention this is realized with a frame system for fixing a panel, in particular a solar panel, to the ground and oriented at an angle of 5-70 degrees to the horizontal plane, said frame system comprising a front end, a rear end, a panel frame for holding the panel and provided with at least one rear support element, said rear support element at one end hingingly attached at or near the rear end to said panel frame for allowing said rear support element to be folded against or in plane with said panel frame and at its other end comprising attachment provisions for attaching the rear support element to the ground, said panel frame further comprising attachment provisions for attaching the front end of the panel to the ground.

The invention furthermore provides a method for providing a photovoltaic power system on a piece of land using the frame system of the preceding claims, said method comprising providing a set of photovoltaic panels, attaching to each photovoltaic panel one of said frame system with said support elements folded against the rear of the panel, transporting said photovoltaic panels with said frame systems to said piece of land, setting up each photovoltaic panel with its frame system on the ground by unfolding said support elements and fixing said legs to the ground.

In an embodiment, said rear support element comprises at least one rear leg at one end hingingly attached at or near the rear end of said panel frame and at the other end comprising a pin that can be inserted into the ground, and said front end comprises at least one front leg, at one end hingingly attached at or near to said front end to said panel frame for allowing said front leg to be folded against or in plane with said panel frame and at its other end comprising a pin that can be inserted into the ground. This embodiment allows easy setup of the panel system.

In an embodiment thereof, the frame system comprises at least two front legs and at least two rear legs. The front legs and/or the rear legs, respectively, can be interconnected via a connecting rod to provide additional ridgidity.

The frame system of the current invention can be attached to a panel, in particular to a solar panel. In this respect, a solar panel can be a photovoltaic panel which converts incoming light into electrical power, or a solar heat panel which uses solar light and heat to heat a liquid, or a combination of a photovoltaic and solar heat panel. The frame system can be attached to a solar panel and allows the panel including frame to remain compact for transport and storage purposes. Furthermore, it allows the panel to be set up at a location on a piece of land very fast. The solar panels and the weights can be easily stacked for transportation and storage. The solar panels are easy to install and un-install, with no specific requirements for the type and condition of the surface. It only requires unfolding of the support elements, and attachment of the support elements to the ground. In this way, it is for instance possible to provide a piece of land which is available for a limited amount of time with a temporary photovoltaic power system. This can only be economically feasible if the costs for setting up such a power plant are minimal. Furthermore, such a power plant should be easily scalable. In this way, pieces of land which remain unused and which are waiting for development can be made productive. Up to now, this was not possible due to the high installation costs of photovoltaic power plants.

With this invention the area, that is (temporarily) not being used, can be used to generate solar electricity. The purpose of the invention is to provide a (temporary) solar power system. The system is easy to transport, install, de-install and store. In fact, a first element of the invention is the concept of using unused parts of land to (temporarily) generate solar energy. The advantage of the system of the invention is that the area does not have to be permanently dedicated for a solar power system. The system is installed just as long as there is no other use for the area. Once the choice is made to use the area for a new purpose, the solar power system can be removed easily, transported, stored and/or placed on another piece of land. In an embodiment, the panel with the frame system integrated and in folded situation can easily be transported to a site, unfolded and installed. Furthermore, it can just as easy be uninstalled, folded, and taken away. In an embodiment, rear and front support structures allow the frame system to be anchored to the ground, for instance by providing parts like for instance pins that can be inserted into the ground.

The panel system allows a panel to be placed on the ground, fixed to the ground, and oriented at an angle of 5-70 degrees to the horizontal plane. In this way, it allows for instance a solar panel to be positioned at an optimal orientation with respect to the sun. Usually, the land part on which the panel system is placed is substantially flat or an almost flat piece of land which is substantially horizontal. In other words, that piece of land is substantially perpendicular with respect to the plumb line. It may, however, also be possible that the piece of land is not flat, and/or it may be at a slope. In these situations, the frame system allows the panel to be oriented towards the sun, and at the defined angle. In case the ground or land on which the panel system is placed is substantially flat and substantially horizontal, the front end will be closest to the ground.

Photovoltaic panels can be provided with a profile, for instance an L- or U-profile, framing the photovoltaic panel. In those cases, the panel frame can be that profile framing the panel. That panel frame can have the support element attached via a hinge. Alternatively, the profile can be part of the panel frame which can have further frame elements attached to those profiles and which frame elements hold the hinged support elements.

In an embodiment, the rear support element comprises at least one rear leg at one end hingingly attached at or near the rear end of said panel frame and at the other end comprising a pin that can be inserted into the ground, and said front end comprises at least one front leg, at one end hingingly attached at or near to said front end to said panel frame for allowing said front leg to be folded against or in plane with said panel frame and at its other end comprising a pin that can be inserted into the ground. This relatively simple construction allows the frame system to be folded in a compact manner to allow easy transportation. It allows fast unfolding and easy placement and anchoring to the ground.

In an embodiment, the frame system comprises at least two front legs and at least two rear legs. In an embodiment, the front legs and/or the rear legs can comprise cross bars interconnecting the legs.

Electricity produced by the photovoltaic panels is centrally collected and preferably converted and delivered to the electricity grid.

In an embodiment said panel frame is provided with a set of support elements, said set of support elements comprising said at least one rear support element and at least one front support element at or near said front end of said panel, said front support element at one end provided with attachment provisions for attaching the front support element to the ground.

In an embodiment, the front support element is displaceably coupled to said panel frame and has a first position substantially parallel to said panel and within the circumference of said panel or in plane with said panel, and a second position extending at least partially from said panel, the front support element and the rear support element each further comprising attachment provisions at their other ends for attaching the support elements to the ground.

In an embodiment, the frame system is adapted for fixing a solar panel to the ground at a desired angle of about 20-60 degrees to the horizontal. To that end, the length of the support elements is adapted. In that respect, if the surface is level and horizontal, the panel will have an angle of about 20-60 degrees with respect to the surface. Usually, the angle will depend on the latitude of the location on earth were the solar panels, in particular photovoltaic panels, are placed. Usually, the length of the rear support element with respect to the front support element determine the angle of the panel. In fact, in an embodiment the length of the rear support element can be set and adapted in order to modify the angle.

In an embodiment of the invention, said front support element comprises at least one front leg which is at one end hingingly attached to said panel frame, hingingly for providing a second position of said front leg in which it extends from said panel. Once the leg is at its position, the leg is blocked, because it is fixed on the ground.

In an embodiment, said front support element comprises at least one front leg which is slidingly attached to said panel frame, for sliding substantially parallel to said panel from a first position within the circumference of said panel to a second position extending at least partially beyond a side of said panel. Thus, an alternative is provided for the hingable front leg.

The hingable front- and rear legs allow adjustment of the angle of the panel with respect to the ground after the panel system is installed, by changing the position of the front and/or rear legs on the ground.

In an embodiment, said panel frame comprises a rectangular frame around the panel, in particular framings said panel, having attachment provisions for attaching the panel support frame to a panel. The rectangular frame can comprise a frame of profiles, like L or U profiles, which is often provided around a solar panel. In such an embodiment, the support element or elements can be directly hingingly attached to this rectangular frame. Alternatively, a separate frame can be provided that hingingly hold the support elements and that can be attached to a panel itself or to a circumferential frame that can be part of the panel.

In an embodiment, at least one part of the frame system comprises a coupling means for coupling said frame system with a further frame system, in an embodiment said coupling means comprises an eye and a cable for passing through said eye. Thus, panel systems can be coupled together or coupled to the ground in order to prevent the panels from being stolen. Alternatively, the panel frame is rectangular, and coupling provisions are provided on the sides other than the front side and rear side.

In an embodiment, the front leg comprises a further hingable part provided for coupling to the rear leg. In this way, it is possible to for instance provide the legs and further hingable parts as parts of a stable triangular construction for holding a panel.

In an embodiment, the length of the legs is adjustable. Thus, it is possible to adjust the angle of a panel with respect to the ground.

In an embodiment the front- and/or rear support does not consist of leg(s), but of another construction as support element like rectangular plate(s), a combination of legs and/or plates or any other stable structure.

The invention further pertains to a photovoltaic power plant comprising a set of photovoltaic panels provided with a frame system described above.

The invention further pertains to a frame system for fixing a panel, in particular a solar panel, to the ground at a desired angle of in general about 5-70 degrees to the surface, said frame system comprising a panel frame for a panel and provided with a set of support elements, said set of support elements comprising at least one front support element and at least one rear support element, the rear support element at one end hingingly attached to said panel frame for allowing said support element to be folded against or in plane with said panel frame, The front support element displaceably coupled to said panel frame and having a first position substantially parallel to said panel and within the circumference of said panel or in plane of said panel, and a second position extending at least partially from said panel, the front support element and the rear support element each further comprising attachment provisions at their other ends for attaching the support elements to the ground, and wherein the front support element is shorter than the rear support element. The rear support element can be fixed or hingingly attached to the ground attachment provision.

The invention further pertains to a frame system for fixing a panel, in particular a solar panel, having a front end and a rear end, to the ground at an angle of in general about 5-70 degrees to the horizontal with said front end closest to said horizontal, said frame system comprising a panel frame for a panel and provided with at least one rear support element, the rear support element at one end hingingly attached at or near a rear end to said panel for allowing said rear support element to be folded against or in plane with said panel frame and at its other end comprising attachment provisions for attaching the rear support element to the ground, said panel frame further comprising attachment provisions for attaching a front end of the panel to the ground.

The invention further pertains to a solar panel with an attached, integrated frame system as described in any of the preceding claims, that can be placed directly on the ground and with holes in the front- and rear-support structures through which pins can be driven into the ground, for instance hammered, for fixation of the panel system to the ground. In an embodiment, the support structures have end plates for resting on the ground. These end plates can be provided with holes through which pins can be inserted in the ground for anchoring the solar panels to the ground.

The invention further pertains to an apparatus comprising one or more of the characterising features described in the description and/or shown in the attached drawings. The invention further pertains to a method comprising one or more of the characterising features described in the description and/or shown in the attached drawings.

The various aspects discussed in this patent can be combined in order to provide additional advantages. Furthermore, some of the features can form the basis for one or more divisional applications.

### DRAWINGS

The invention will be further elucidated referring to an embodiment of a frame system shown in the attached drawings, showing in:

FIG. 1 a side view of a panel with frame system in installed state.

FIG. 2a a side view of a panel with frame system in folded state.

FIG. 2b a side view of an alternative to FIG. 2a.

FIG. 3 a front view of one panel and frame system of FIG. 1.

FIG. 4 a step in installing the frame system of FIG. 1.

FIG. 5 a following step after the step of FIG. 4.

FIG. 6 a front view of an interconnection of an alternative frame system.

FIG. 7 a detailed view of FIG. 6.

FIG. 8 an alternative embodiment of the frame system.

FIG. 9 an alternative embodiment of the frame system.

FIG. 9a an embodiment combining the embodiments of FIG. 2b and FIG. 9 in cross sectional view.

FIG. 9b the embodiment of FIG. 9a seen from below.

FIG. 10 an alternative embodiment with interconnectable rectangular plates as support elements.

FIG. 11 an embodiment of the frame system where front support element and rear support element are plates.

### DESCRIPTION

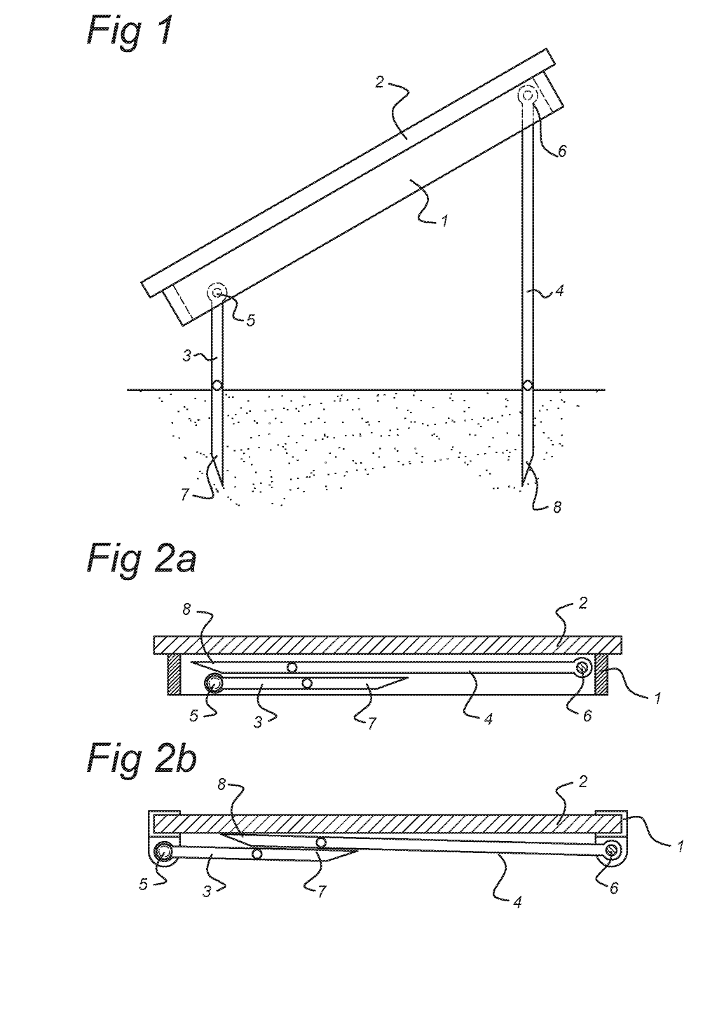

In FIG. 1, a side view of an embodiment of a frame system with a panel is shown. A panel frame 1 carrying a panel 2 comprises a front support element 3, here a leg 3, and a rear support element 4, here also leg 4. Front leg 3 is coupled via a hinge 5 to panel frame 1. The hinge 5 allows the front leg 3 to be folded against or within panel frame 1. In fact, front leg 3 can be folded within the circumference of panel 2, in particular within the circumference of panel frame 1. The rear leg 4 is coupled to panel frame 1 via a hinge 6. The hinge 6 allows the rear leg 4 to be folded against or within panel frame 1. In particular, the hinge allows the rear leg to be folded within the circumference of panel 2, in particular within the circumference of panel frame 1.

In FIG. 2a, an embodiment is shown in which the front and rear leg or legs are folded against the panel 2. In this embodiment a frame of profile elements 1 is mounted against the underside of a panel 2. In an alternative embodiment, shown in FIG. 2b, for instance a solar panel is produced with a frame of profile elements 1 around it. Thus, the profile elements form a framework which frames the panel. Attached to this frame of profile elements, the foldable legs can be provided. Thus, the frame of profile elements 1 can have a function of reinforcing the panel 2, and on the same time providing an attachment for the legs and form a basis for the panel frame. Thus, in a very simple way a panel can be provided with support elements.

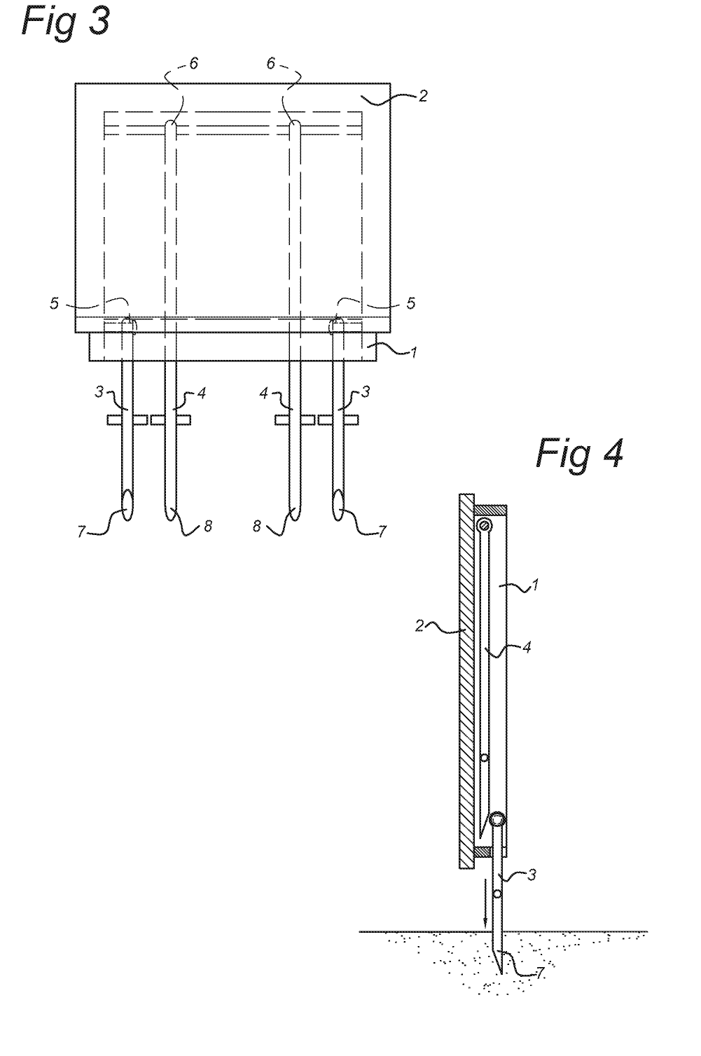

The front leg 3 further has a ground mounting end. In the embodiment of FIG. 1, the ground mounting end comprises a ground pin 7 which is inserted in the ground. The rear leg 4 of FIG. 1 also comprises a ground mounting end. In an embodiment of FIG. 1, the ground mounting end comprises a ground pin 8 which is inserted in the ground. FIG. 3 shows a front view of the panel with panel frame of FIGS. 1 and 2. In this embodiment, two front legs 3 and two rear legs 4 are used. Alternatively, it may be possible to use one front leg 3 and/or one rear leg 4. This may put, however, a more heavy load on the coupling of leg and panel attachment frame. The legs can have a round cross section, be square, U-shaped or have any other cross section. Between the legs one or more reinforcement provisions, like additional bars, can be provided to provide additional rigidity.

Instead of legs, it is also possible to use for at least one of the front legs and the rear legs a panel or plate, optionally provided with one or more ground pins. An advantage of for instance using a panel or plate for the rear leg or rear legs is that it may provide a slanted closes surface which can reduce the wind load induced by wind coming from behind. Alternatively, to get the same result, the rear legs can be provided with a panel which may be removable, or they can be provided with for instance a canvas or a sheet of tarpaulin. Such a sheet can also for instance cover several adjacent panels and panel frames for reducing the wind load for wind coming from behind.

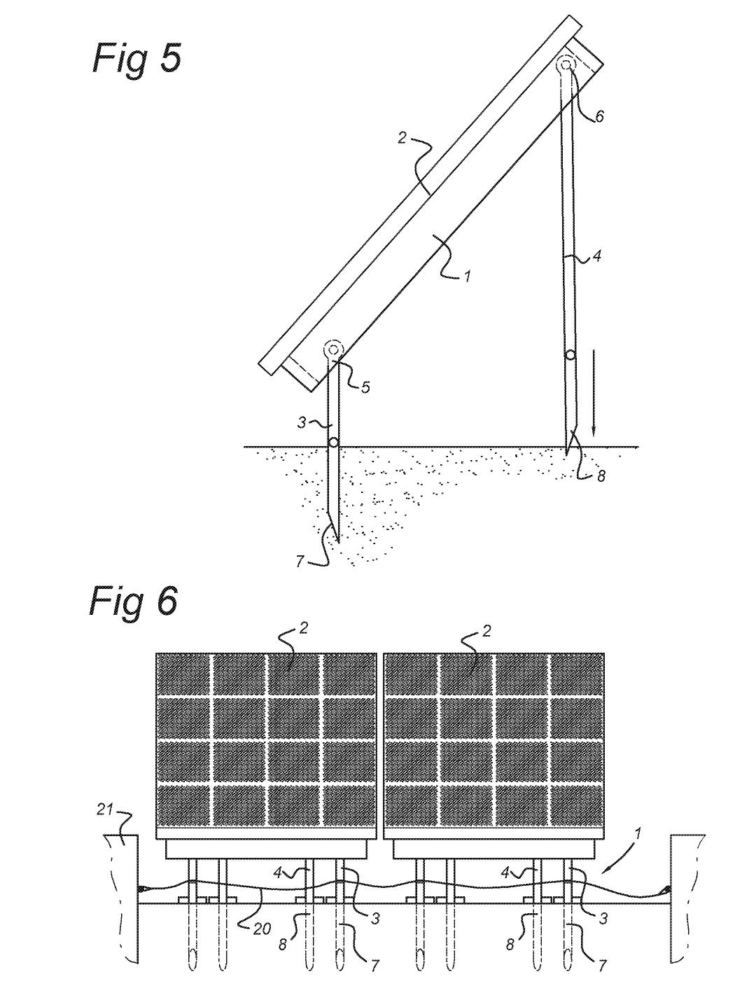

In FIGS. 4 and 5 two steps of placing the panel-panel frame assembly is shown. In FIG. 4, first the front legs 3 are unfolded and positioned in this embodiment almost parallel to the panel 2. Next, the front legs 3 are inserted in the ground, here simply by pushing panel 2 downwards, thus pushing ground pin part 7 of front leg 3 into the ground. In FIG. 5, a next step is illustrated. Ground pin 7 is fully pushed into the ground, rear leg 4 is unfolded and the panel 2 and panel frame 1 rotate about the rotational axis provided by hinges 5. Thus, rear leg 4 is placed in position with its ground pin 8 resting on the ground and ready to be pushed into the ground.

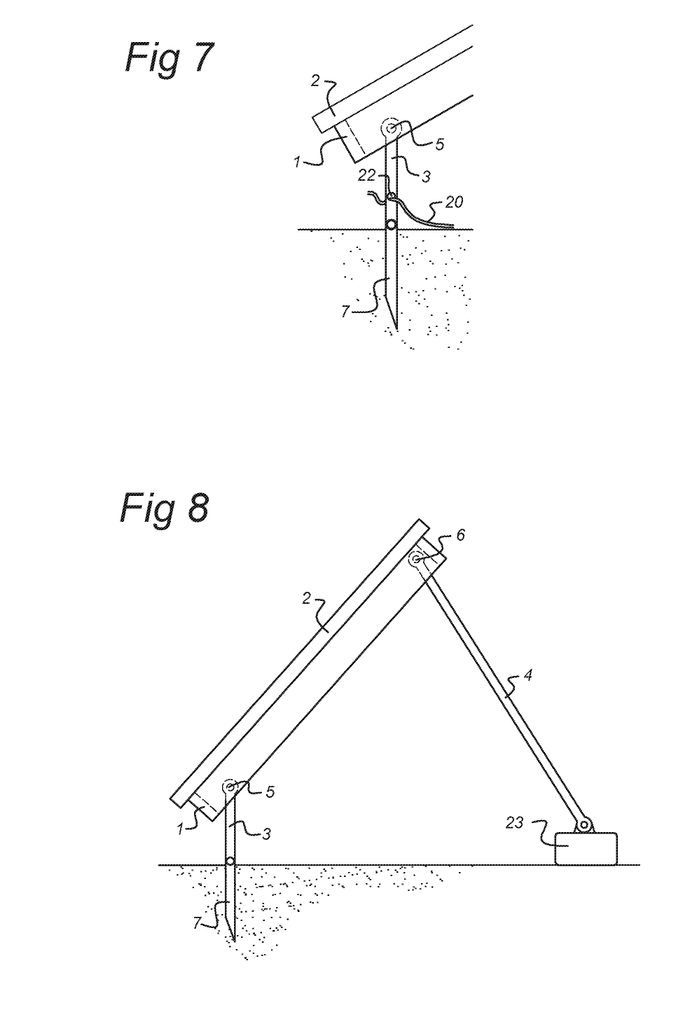

In FIG. 6, a front view of in this embodiment two installed panels 2 with panel frames of FIGS. 1-5 are shown. In this embodiment, a cable 20 is attached to two of the rear legs of each panel frame 2. The cable 20 is here attached to two blocks 21 at each end of the cable 20. Alternatively, other means of fixing the cable ends securely to the ground may be provided. In an alternative embodiment, so called ground anchors may be used. In the drawing, the cable 20 is not tensioned, thus only providing a means for preventing the rear legs to be taken out of the ground. In that way, a theft prevention means is provided. Other more complex theft prevention means are also considered, for instance providing the panels or panel frames with a hidden GPS device, or providing a closed circuit alarm which sounds or activates a silent alarm when the circuit is broken, i.e. one or more panels are removed. Alternatively, the cable or a connecting rod, which is more complex, however, can be tensioned. In that way, the cable provided an additional fixing means for fixing the panel frames to the ground. It may even function to mechanically couple panel frames to one another. In FIG. 7, a detail for connecting the cable 20 to a leg is shown. In the specific leg 3, an eye 22 is provided for passing the cable 20 through. In this embodiment, the leg 3 is provided with a through hole 22 for passing the cable 20 through.

FIG. 8 shows an alternative embodiment of the panel frame 2. In this embodiment, the rear leg 4 is fixed to an alternative attachment provision for positioning leg to the ground. A weight is provided which rests on the ground, but which can alternatively also rest at least partially into the ground. The weight is here hingingly coupled to an end of rear leg 4. In an embodiment, both the front leg 3 and the rear leg 4 can be provided with such an attachment provision.

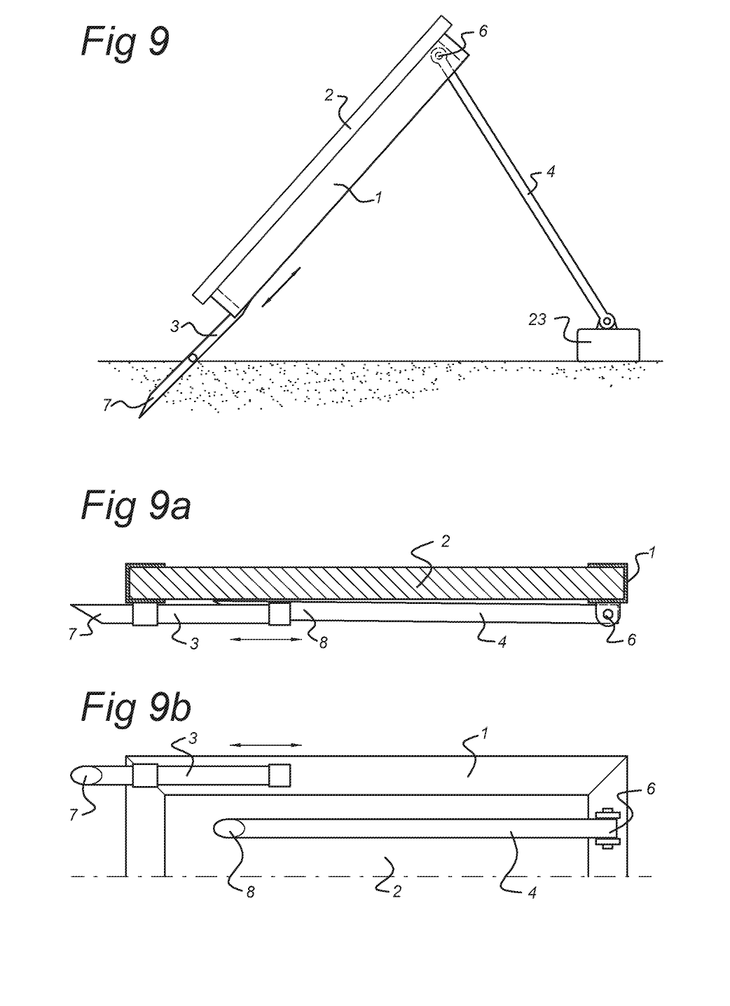

In FIG. 9, an alternative embodiment of the front leg or legs 3 is provided. Here, it is combined with the attachment provision for the rear leg of FIG. 8, but alternatively the ground pin 8 of FIGS. 1-7 can be used. In this embodiment, the front leg or front legs are slidingly attached to panel frame 2, for allowing front leg 3 to slide substantially parallel to panel 1. Thus, for installing the panel and panel frame, first front leg or front legs 3 can be slided into the position shown in FIG. 9, then the ground pin 7 of the front leg or front legs 3 of panel 2 and panel frame 1 pushed into the ground at the desired angle, and rear leg 4 is unfolded and attached to weight 23. This embodiment allows a more stable positioning, the hinging front leg or front legs allows more precise angle positioning. When using hinges which can be locked in a set angle position, for instance locked in any desired angle position continuously, it is possible to combine both advantages.

In FIGS. 9a and 9b, an embodiment is shown which combines FIG. 9 and FIG. 2b. In this schematic embodiment, a panel is held in an framework of U-profiles. Attached to these U-profiles, are a sliding front support 3, here a front leg 3, and a hingable rear support, here a rear leg 4. In fact, FIG. 9a is a cross section of FIG. 9b just outside front support 3.

Front leg 3 can slide in the direction of the arrow. It can have a fixing provision for fixing it in the position in which is seen in FIG. 9, i.e., completely extending, allowing the ground pin part 7 to be pushed into the ground.

Rear leg 4 can be hinged in the direction out of the paper. Hinge 6 can also have a fixing provision to fix the rear leg in a desired position. Instead of providing the support elements 3, 4 on the U-profile at the back of the panel, it is also possible to attach the support elements to the side location of the U-profile. Thus, the thickness of the panel with support frame does not increase.

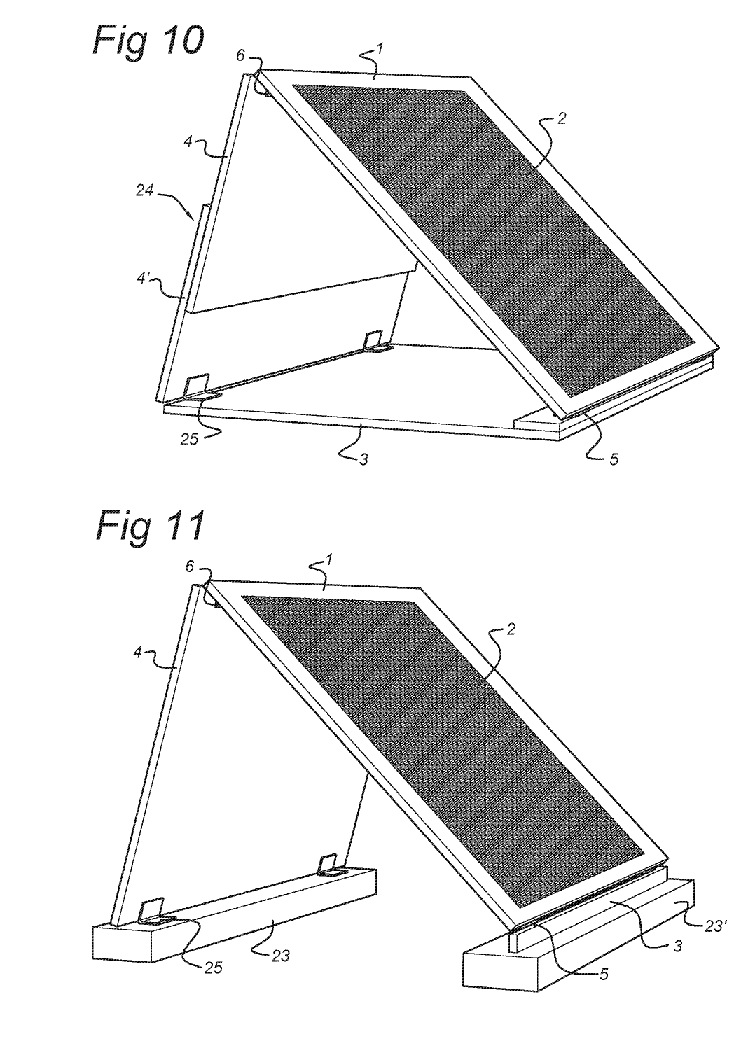

In FIG. 10, a further embodiment of the invention is disclosed. In this embodiment, the front support element and rear support element are again closed support panels. Front panel 3 is hinged backwards and has a coupling part 4′ which is hingingly connected via hinges 25 to the end of front panel 3. This coupling part 4′ is coupled to the rear panel 4. Thus, front panel 3, rear panel 4 and coupling part 4 form two sides of a triangle. In this embodiment, the back of the frame system is closed, thus avoiding high wind load for wind coming from behind. This embodiment can also be designed with legs instead of panels or with a combination of legs and panels. The front panel and/or the rear panel can be attached to a weight, for instance like the weight shown in FIG. 9. Alternatively, a weight can be placed below the panel on top of panel 3. The weight will then rest within the triangle of panels of FIG. 10.

In FIG. 11 an alternative embodiment of the solar panel frame system is shown. In this embodiment the front and rear support elements are both rectangular plates. The front support plate is hingingly attached to the panel frame and fixed on a weight. The rear support plate is hingingly attached to both the solar panel frame and to the weight. The advantages of this system is that the rectangular plates block the wind and provide stability during installation. This system can also be designed with a combination of leg(s) and plate(s).

It will also be clear that the above description and drawings are included to illustrate some embodiments of the invention, and not to limit the scope of protection. Starting from this disclosure, many more embodiments will be evident to a skilled person which are within the scope of protection and the essence of this invention and which are obvious combinations of prior art techniques and the disclosure of this patent.

1-19. (canceled)

20. A frame system for a solar panel, comprising:
a front end;
a rear end;
a panel frame which holds the solar panel and provided with a rear support element which is hingingly attached at a first end to said panel frame to allow said rear support element to be folded against or in plane with said panel frame, the rear support system having a second end comprising first attachment provisions to attach the rear support element to the ground, said panel frame further having second attachment provisions to attach the front end of the panel to the ground,
wherein the frame system is configured to fix the solar panel to the ground and oriented at an angle of 5-70 degrees to the horizontal plane.

21. The frame system of claim 20, wherein said rear support element comprises a rear leg at one end hingingly attached at a rear end of said panel frame and at the other end comprising a pin that is insertable into the ground, and said front end comprises at least one front leg, at one end hingingly attached at or near to said front end to said panel frame to allow said front leg to be folded against or in plane with said panel frame and at its other end comprising a pin that can be inserted into the ground.

22. The frame system of claim 21, further comprising at least two front legs and at least two rear legs.

23. The frame system of claim 20, wherein said panel frame is provided with a set of support elements, said set of support elements comprising said at least one rear support element and at least one front support element at or near said front end of said panel, said front support element at one end provided with attachment provisions to attach the front support element to the ground.

24. The frame system of claim 23, wherein:
said front support element is displaceably coupled to said panel frame and has a first position substantially parallel to said panel and within the circumference of said panel or in plane with said panel, and a second position extending at least partially away from said panel; and
the front support element and the rear support element each further comprise attachment provisions at their other ends to attach the support elements to the ground.

25. The frame system of claim 23, wherein the front support element is shorter than the rear support element.

26. The frame system of claim 23, wherein said at least one front support element is at one end hingingly attached to said panel frame to provide a second position of said front support element in which it extends from said solar panel.

27. The frame system of claim 23, wherein said at least one front support element is slidably attached to said panel frame, to slide substantially parallel to said panel from a first position within the circumference of said panel to a second position extending at least partially beyond a side of said panel.

28. The frame system of claim 20, wherein said panel frame comprises a rectangular panel support frame having attachment provisions to attach the panel support frame to the solar panel.

29. The frame system of claim 20, wherein in use, the rear support element is hingingly attached to a weight on the ground.

30. The frame system of claim 20, wherein at least one part of the frame system comprises a coupling mechanism to couple said frame system with a further, similar frame system, said coupling mechanism comprising an eye and a cable for passing through said eye.

31. The frame system of claim 20, wherein said front support element comprises a further hingable part provided for coupling to said rear support element.

32. The frame system of claim 20, wherein the length of the support elements is adjustable.

33. The frame system of claim 20, wherein at least one of said support elements comprises at least one leg.

34. The frame system of claim 20, wherein at least one of said support elements comprises a plate.

35. A solar panel comprising:
a solar panel body;
a frame system having:
a front end;
a rear end;
a panel frame which holds the solar panel body and provided with a rear support element which is hingingly attached at a first end to said panel frame to allow said rear support element to be folded against or in plane with said panel frame, the rear support system having a second end comprising first attachment provisions to attach the rear support element to the ground, said panel frame further having second attachment provisions to attach the front end of the solar panel body to the ground,
wherein the frame system is configured to fix the solar panel to the ground and oriented at an angle of 5-70 degrees to the horizontal plane,
wherein said front support element and said rear support element are collapsible and configured to be placed on the ground or fixed to an attachment provision that is placed on or in the ground.

36. The solar panel of claim 35, wherein the frame system is an integrated frame system configured for placement directly on the ground and with holes in said front support element and said rear support element through which pins are driven into the ground to thereby fix the solar panel to the ground.

37. The solar panel of claim 35, wherein said panel frame is provided with a set of support elements, said set of support elements comprising said at least one rear support element and at least one front support element at or near said front end of said panel, said front support element at one end provided with attachment provisions to attach the front support element to the ground.

38. The solar panel system of claim 37, wherein:
said front support element is displaceably coupled to said panel frame and has a first position substantially parallel to said panel and within the circumference of said panel or in plane with said panel, and a second position extending at least partially away from said panel; and
the front support element and the rear support element each further comprise attachment provisions at their other ends to attach the support elements to the ground

39. A method for providing a photovoltaic power system on an area of land, said method comprising:
attaching a plurality of photovoltaic panels to a corresponding frame system having a panel frame which holds the photovoltaic panel and provided with support elements folded against a rear of the photovoltaic panel;
transporting said photovoltaic panels with said frame systems to said area of land;
arranging each photovoltaic panel and corresponding frame system on the ground by unfolding said support elements; and
fixing said support elements to the ground.
